(19) United States
(12) Patent Application Publication
(10) Pub. No.: US 2009/0242385 A1
(43) Pub. Date: Oct. 1, 2009

(54) METHOD OF DEPOSITING METAL-CONTAINING FILMS BY INDUCTIVELY COUPLED PHYSICAL VAPOR DEPOSITION

(75) Inventors: Rodney L. Robison, East Berne, NY (US); Frank M. Cerio, JR., Albany, NY (US)

Correspondence Address: Tokyo Electron U.S. Holdings, Inc., 4350 West Chandler Blvd., Suite 10/11, Chandler, AZ, 85226, US

(73) Assignee: TOKYO ELECTRON LIMITED, Tokyo (JP)

(21) Appl. No.: 12/058,607

(22) Filed: Mar. 28, 2008

(51) Int. Cl. C23C 14/34

(52) U.S. Cl. 204/192.11

(57) ABSTRACT

A method for depositing a metal-containing film on a substrate using an inductively coupled (ICP) physical vapor deposition (PVD) system. The ICP PVD deposition is performed under process conditions that thermalize neutral sputtered metal atoms by collisions with a process gas and minimize or eliminate exposure of ions to the substrate.

### FIELD OF THE INVENTION

The invention relates to deposition of metal-containing films on semiconductor substrates, and more particularly, to inductively coupled physical vapor deposition of metal-containing films for high volume manufacturing of advanced semiconductor devices.

### BACKGROUND OF THE INVENTION

Metal-containing films are widely used in semiconductor devices and ultra-large-scale integrated circuits. For example, titanium nitride films have been used in semiconductor devices as a diffusion barrier for preventing metal diffusion into other materials. Titanium nitride films have been employed as a diffusion barrier against copper (Cu) diffusion, for example in contacts, vias and trenches. Other uses of titanium nitride films include metal wiring, contact plug, and upper electrode of a capacitor. Titanium nitride films are effective in preventing diffusion of dopants and other ions toward a lower region of a semiconductor device, such as toward a gate of a transistor, a dielectric layer of a capacitor, or a semiconductor substrate.

Of the several processes that can be used to deposit titanium nitride films and other metal-containing films, including physical vapor deposition (PVD), chemical vapor deposition (CVD), and atomic layer deposition (ALD), PVD technology has advantages in simplicity and process flexibility, but it can suffer from poor step coverage over high-aspect ratio features found in many advanced semiconductor devices. Existing PVD technology has been extended to below 45 nm (nanometer) back-end-of-line (BEOL) applications by increasing the ionization rate of the sputtered material to improve step coverage. Since the device features in BEOL processing are usually far removed from sensitive areas of a device, for example a gate area of a transistor, the high-ionization approach does not significantly affect device performance. For front-end-of-line (FEOL) processing, however, metal-containing films may be deposited directly onto or near the sensitive areas of a device, thereby reducing or precluding the use of conventional PVD or ionized PVD (iPVD) technology due to potential ion and plasma damage in the sensitive areas. Accordingly, there is a need to further develop PVD technology, including processing conditions, to facilitate deposition of metal-containing films in high volume manufacturing of advanced semiconductor devices.

### SUMMARY OF THE INVENTION

Embodiments of the invention describe a method of operating an Inductively Coupled Plasma (ICP) Physical Vapor Deposition (PVD) system containing a metal (sputtering) target, a dielectric window, and an antenna, to deposit a metal-containing film (e.g., a metal film, a metal nitride film, a metal oxide film, a metal oxynitride film, a metal carbide film, or a metal carbonitride film) on a substrate. Embodiments of the invention provide a method for deposition of metal-containing films for high volume manufacturing of semiconductor devices on large patterned substrates such as 200 mm, 300 mm, or even larger diameter substrates (wafers).

Embodiments of the invention provide plasma processing conditions for ICP PVD processing, including low ICP plasma power, that result in substantially only neutral metal atoms being sputtered from a metal target. Furthermore, the low ICP power and other processing conditions, including chamber pressure and distance between the metal target and the substrate, are selected such that the sputtered neutral metal atoms are not ionized by the plasma and are further thermalized by gas phase collisions prior to reaching proximity of the substrate surface where they form a metal-containing film on the substrate.

According to one embodiment of the invention, a method is provided for operating an ICP PVD system to deposit a titanium nitride film in metal mode on a substrate. The method includes positioning the substrate on a substrate holder within a process chamber of the ICP PVD system, where the ICP PVD system further contains a titanium target, a dielectric window, and an antenna. The method further includes flowing a process gas containing argon gas and nitrogen gas into the process chamber, applying electrical power to the titanium target, creating an ICP argon ion sputtering plasma in the process chamber by applying RF power to the antenna to sputter substantially only neutral titanium atoms from the titanium target. The neutral titanium atoms react with the nitrogen gas proximate and/or on the substrate, where a process chamber pressure and distance between the titanium target and the substrate are selected to thermalize the neutral titanium atoms by collisions with the process gas prior to reaching the substrate. The method further includes removing the substrate from the process chamber.

### BRIEF DESCRIPTION OF THE DRAWINGS

A more complete appreciation of the present invention and many attendant advantages thereof will be readily obtained as the same becomes better understood by reference to the following detailed description when considered in connection with the accompanying drawings, wherein:

FIG. 1A illustrates an exemplary block diagram of a processing system according to an embodiment of the invention;

FIG. 1B illustrates an exemplary block diagram of a processing system according to an alternate embodiment of the invention; and

FIG. 2 illustrates a simplified flow diagram of a method of operating a processing system to perform a titanium nitride deposition process according to an embodiment of the invention.

### DETAILED DESCRIPTION OF SEVERAL EMBODIMENTS

Embodiments of the invention describe processing methods that are suitable for deposition of metal-containing films for high volume manufacturing of semiconductor devices on large patterned substrates such as 200 mm, 300 mm, or even larger diameter substrates (wafers). Embodiments of the invention may be used to deposit metal-containing films; including a metal film, a metal nitride film, a metal oxide film, a metal oxynitride film, a metal carbide film, or a metal carbonitride film, or a combination thereof. The metal nitride films can, for example, contain titanium nitride, tantalum nitride, or tungsten nitride films. Deposition of titanium nitride films is described below, but those skilled in the relevant arts will readily realize that other metal-containing films may be deposited using the teachings described herein. For example, a tantalum sputtering target may be used when depositing a tantalum nitride film and a tungsten sputtering target may be used when depositing a tungsten nitride film.

One skilled in the relevant art will recognize that the various embodiments may be practiced without one or more of the specific details, or with other replacement and/or additional methods, materials, or components. In other instances, well-known structures or operations are not shown or described in detail to avoid obscuring aspects of various embodiments of the invention. Similarly, for purposes of explanation, specific numbers, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

In the sputtering of a titanium target that utilizes a process gas containing argon gas (Ar) and nitrogen gas (N₂) to deposit a titanium nitride film on a substrate, the sputtering process can be operated in two different modes; metal mode or poison mode. The two different modes are fundamentally determined by the condition of the titanium target surface during the deposition process.

In metal mode, argon ions created from the process gas sputter titanium from the titanium target and keep the titanium target clean and metallic. Therefore, the argon ions sputter titanium from the titanium target and the titanium reacts with nitrogen gas in the process environment and/or on the substrate surface to form a titanium nitride film on the substrate surface.

In poison mode, there is sufficient nitrogen gas in the processing environment to continuously nitride the titanium target to a sufficient thickness that the argon ions cannot remove rapidly. The argon ions still sputter the nitrided titanium target, thereby sputtering a titanium nitride compound from the target and the titanium nitride compound deposits on the substrate surface. Thus, in poison mode, the reaction between the neutral titanium metal and the nitrogen gas occurs prior to formation of titanium nitride on the substrate surface.

As a result, titanium nitride films deposited by the two different modes can have very different properties, including different electrical resistivity and nitrogen/titanium atomic ratio. Poison mode is commonly used for titanium nitride deposition due to the relatively large process window provided by high nitrogen gas flows that ensure sufficient flow of nitrogen gas over the substrate to complete nitridation of the titanium nitride compound. One drawback of the poison mode is the potentially high electrical resistivity of the titanium nitride films that make them unsuitable for manufacturing many advanced semiconductor devices.

Although metal mode is sometimes preferred for deposition of titanium nitride materials due to potentially high deposition rates and lower electrical resistivity of the titanium nitride films, metal mode suffers from a relatively narrow process window in terms of nitrogen gas flow and nitrogen gas concentration in the process chamber. Furthermore, many advanced semiconductor devices contain active regions that are susceptible to plasma damage (e.g., ion implantation, surface roughening) if exposed directly to ions and electrons from a plasma processing environment. For example, a titanium nitride film can be used as a gate electrode in a gate stack that is proximate active device regions that are susceptible to plasma damage.

In view of these needs, the inventors have developed ICP PVD processing that achieves deposition of low-resistivity titanium nitride films in metal mode for high volume manufacturing of advanced semiconductor devices. In particular, unlike conventional titanium nitride ICP PVD processing, embodiments of the invention utilize plasma processing conditions, including low ICP plasma power (e.g., about 500 watts (W)), that result in neutral titanium atoms being sputtered from the titanium target. Furthermore, the low ICP power and other processing conditions, including the chamber pressure and the distance between the titanium target and the substrate, are selected such that the sputtered neutral titanium atoms are not ionized by the plasma and are further thermalized (slowed down) by gas phase collisions prior to reaching the substrate surface where they are nitrided to form a titanium nitride film on the substrate. For example, typical kinetic energies of titanium atoms ejected from a titanium target can be of the order of a few electron volts (eV) (e.g., approximately 2 eV), whereas the thermalized titanium atoms may have kinetic energy less than one eV (e.g., of the order of approximately 0.1 to 0.3 eV).

According to embodiments of the invention, since the titanium atoms arriving at the substrate are neutral and thermalized, any potential substrate damage due to the titanium atoms impinging on the substrate is minimized or eliminated. For comparison, other titanium nitride deposition methods commonly include exposing the substrate to titanium atoms or titanium nitride molecules with high kinetic energy due to low process chamber pressure and the near absence of thermalization by gas phase collisions.

Furthermore, according to an embodiment of the invention, the substrate holder may not be coupled to a radio frequency (RF) bias in order to further reduce or prevent (relatively energetic) ions from the plasma environment interacting with the substrate surface. For comparison, conventional ICP PVD processes typically use high energy ICP plasma power, for example greater than 1,000 W, or greater than 5 kW, resulting in significant ionization of the sputtered titanium atoms. Thereafter, when a substrate is RF biased by coupling RF power to the substrate through an electrode in the substrate holder, the ion energy for ions incident on the substrate is increased. For example, when the substrate is DC floating and coupled to an RF bias, ions are drawn through the plasma sheath to the substrate during the negative half-cycle of the RF waveform, and the plasma sheath collapses and electrons are drawn to the substrate during the positive half-cycle of the RF waveform. Since the substrate is DC floating, no net DC current may exist. As a result, a DC self-bias is established at the substrate (i.e., a negative DC offset of the RF waveform). This DC self-bias is approximately equivalent to the mean ion energy for ions accelerated through the plasma sheath to the substrate. The elevated ion energy can cause damage to active device regions that are susceptible to plasma damage. For example, performance of a gate stack can be affected by residual electrical charges in the titanium nitride film and other materials due to ions impacting on the substrate during deposition of the titanium nitride film.

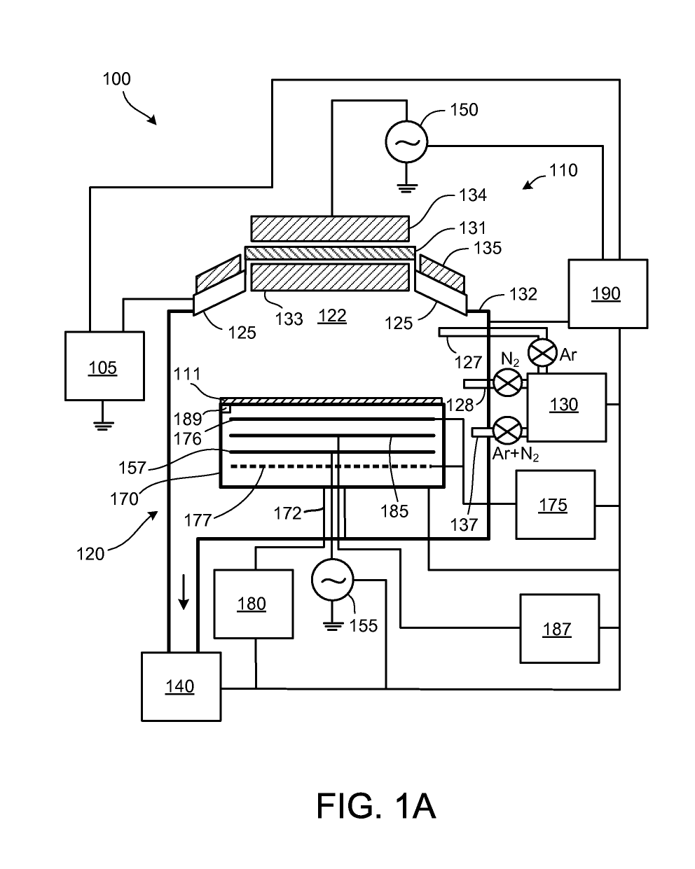

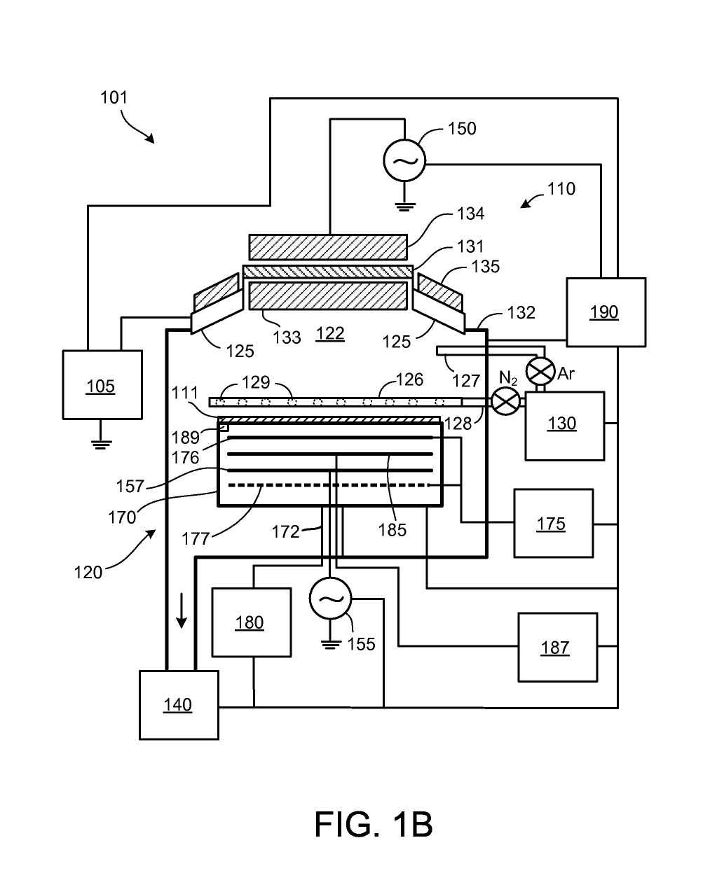

FIG. 1A illustrates an exemplary block diagram of a processing system according to an embodiment of the invention. In the illustrated embodiment, a PVD system 100 is shown. The PVD system 100 includes an PVD processing module 110 comprising a process chamber 120, a DC power source 105 coupled to a titanium target 125 that is coupled to the process chamber 120, a process gas supply system 130, a pressure control system 140, a RF generator 150, a RF bias generator 155 that can be coupled to an electrode 157 in a temperature-controlled substrate holder 170, a backside gas supply system 180 that can be coupled to the substrate holder 170, and an electrostatic chuck (ESC) electrode 185 connected to an ESC control unit 187.

According to other embodiments of the invention, the titanium target 125 may be replaced by a metal target 125 containing tantalum, tungsten, vanadium, chromium, manganese, iron, nickel, copper, zinc, yttrium, zirconium, niobium, molybdenum, ruthenium, rhodium, palladium, silver, cadmium, hafnium, rhenium, iridium, platinum, gold, or aluminum. The metal target 125 may be utilized to deposit a metal-containing film containing sputtered metal from the metal target 125. The metal-containing film can contain a metal film, a metal nitride film, a metal oxide film, a metal oxynitride film, a metal carbide film, or a metal carbonitride film, or a combination thereof.

The PVD system 100 contains a controller 190 coupled to the process chamber 120, the DC power source 105, the process gas supply system 130, the pressure control system 140, the RF generator 150, the RF bias generator 155, the substrate holder 170, a temperature control system 175, the backside gas supply system 180, and the ESC control unit 187.

The PVD processing module 110 contains an antenna 134, an RF transmissive window 131 coupled to the antenna 134, a louvered deposition baffle 133 coupled to the window 131, and the titanium target 125 coupled to the process chamber 120. RF power can be supplied to the antenna 134 from the RF generator 150, and the RF power transmitted through the window 131 creates an inductively coupled plasma (ICP) in a plasma region 122 of the process chamber 120. According to embodiments of the invention, the inductively coupled plasma is mainly confined to the plasma region 122 near the titanium target 125, the window 131, and the baffle 133.

The antenna 134 can be electrically connected to the RF generator 150 using a RF matching network (not shown). The RF generator 150 can be used to selectively energize or power the antenna 134. The RF generator 150 can provide a time-varying RF current at a frequency between about 100 kHz and about 100 MHz that is supplied to the antenna 134 at an ICP power ranging between about 100 W and about 10,000 W. For example, an operating frequency of approximately 13.56 MHz can be used. Alternately, other frequencies can be used. When energized by the RF generator 150, the antenna 134 radiates isotropic RF electromagnetic fields. A metallic outer enclosure or cage (not shown) can be used to surround the antenna to confine the radiated RF electromagnetic fields therein to ensure the safety of nearby persons and to prevent electromagnetic interference with surrounding electronics.

Examples of PVD systems are described in U.S. Pat. Nos. 6,287,435; 6,080,287; 6,197,165 and 6,132,564, and these patents are hereby expressly incorporated herein by reference.

The antenna 134 can be positioned outside of the process chamber 120 behind the window 131 in the chamber wall 132. The louvered deposition baffle 133, preferably formed of a slotted metallic material, is located inside of the process chamber 120 closely spaced from the window 131 to shield the window 131 from deposition. The controller 190 can be used to determine the amount of ICP power to provide and when to have it applied to the antenna 134.

The PVD system 100 contains substrate holder 170 that includes an ESC electrode 185 and can be coupled to the process chamber 120 using a Z-motion drive 172. The Z-motion drive 172 can be used to adjust the substrate-to-target distance (gap) to provide the best deposition uniformity. The controller 190 can be used to determine the substrate-to-target distance required during the titanium nitride deposition process and provide the control data to the Z-motion drive 172 when it is required. During a titanium nitride deposition process, the substrate-to-target distance can typically be about 150 to about 300 mm.

The substrate holder 170 can accommodate a 200 mm substrate, a 300 mm substrate, or a larger substrate. For example, the substrate 111 can be transferred into and out of process chamber 120 through an opening (not shown) that is controlled by a gate valve assembly (not shown). In addition, the substrate 111 can be transferred on and off the substrate holder 170 using a robotic substrate transfer system (not shown). In addition, the substrate 111 can be received by substrate lift pins (not shown) housed within substrate holder 170 and mechanically translated by devices housed therein. Once the substrate 111 is received from the transfer system, it can be lowered to an upper surface of the substrate holder 170 for processing.

During processing, the substrate 111 can be held in place on top of the substrate holder 170 using ESC electrode 185. Alternately, other clamping means may be used.

In addition, the substrate temperature can be controlled when the substrate is on the temperature-controlled substrate holder 170. The substrate holder 170 can include a heater assembly 176 and a cooling assembly 177 that can be coupled to the temperature control system 175. The heater assembly 176 and the cooling assembly 177 can be used along with one or more backside gases to establish the desired substrate temperature. The controller 190 can be used to determine and control the substrate temperature. For example, the cooling assembly 177 may include fluid passages (not shown) in the substrate holder 170 and the appropriate temperature controls. For example, heat generated in the substrate 111 during plasma processing can be extracted efficiently by the substrate holder 170 to keep the substrate 111 at a substantially constant temperature, or the heat can be used to increase the substrate temperature.

Gas channels (not shown) can be used to direct a backside (heat transfer) gas, such as helium gas or argon gas, between the top of the substrate holder 170 and the facing surface of the substrate 111. For example, a two-zone system may be used to establish different and independent backside pressure values for a center portion and an edge portion thereby providing a different thermal conductivity between the substrate holder 170 and different portions of the substrate 111.

One or more temperature sensors 189 can be positioned at one or more locations on or within the substrate holder 170 and can be coupled to the controller 190 that converts signals from the temperature sensors 189 to provide an indication of the temperature of different portions of the substrate holder 170. The temperature of the substrate holder 170 can be used to determine the temperature of the substrate 111 and the controller 190 can provide feedback information to the temperature control system 175 and the backside gas supply system 180 for regulating the temperature of substrate 111.

According to one embodiment of the invention, the substrate 111 and the substrate holder 170 can be electrically floating during the plasma deposition process. This can create a self-bias of 10-20V on the substrate 111 during the plasma processing. According to another embodiment of the invention, the substrate 111 and the substrate holder 170 may be grounded. According to yet another embodiment of the invention, RF bias power can be supplied to the electrode 157 in the substrate holder 170 using the RF bias generator 155, and can be used to provide a substrate bias. The controller 190 can be used to determine the amount of RF bias power to provide and when to have it applied to the substrate holder 170. For example, RF bias power can be turned on to a level appropriate during titanium nitride deposition processes to control the bias on the substrate 111 to improve and affect the process.

The operating frequency for the RF bias generator 155 can range from 1 MHz to 100 MHz. The RF bias generator 155 can be used to selectively apply a bias potential that controls acceleration of positively charged plasma components toward the substrate 111. The bias potential provided by the RF bias generator 155 substantially determines the kinetic energies of positive ions attracted to the substrate from the plasma. The RF bias generator 155 can, for example, operate at a frequency of about 13.56 MHz and at a power between about 100 W and about 1000 W. Alternately, other frequencies can be used, such as 2 MHz or 27 MHz.

Process gas can be provided to the process chamber 120 by the process gas supply system 130. The process gas can contain argon gas (Ar) and nitrogen gas (N₂) gas for depositing a titanium nitride film on the substrate 111. The argon gas may be introduced into the process chamber 120 by the gas line 127 and the nitrogen gas may be introduced into the process chamber 120 using the gas line 128. Alternately, other configurations may be used for introducing the argon gas and the nitrogen gas into the process chamber 120. For example, the argon gas and the nitrogen gas may be introduced into the process chamber below the substrate 111 using gas line 137. As schematically illustrated in FIG. 1A, argon gas may be introduced into the process chamber 120 proximate the titanium target 125 and the nitrogen gas may be introduced into the process chamber 120 proximate the substrate 111.

According to other embodiments of the invention, the process gas can contain a sputtering gas (e.g., Ar), and a reactant gas that reacts with the neutral metal atoms proximate to and/or on the substrate. The reactant gas can contain a nitrogen-containing gas (e.g., N₂ or NH₃), an oxygen-containing gas (e.g., O₂ or H₂O), a nitrogen- and oxygen-containing gas (e.g., NO, N₂O, or NO₂), or a carbon-containing gas (e.g., CH₄ or C₂H₆), or a combination thereof.

Chamber pressure can be controlled using the pressure control system 140. The pressure control system 140 can, for example, contain a vacuum pump (not shown) and a throttle valve (not shown). The chamber pressure can be maintained at a low pressure, for example below 100 mTorr, by the pressure control system 140. The controller 190 can be used to control the pressure control system 140, and/or the process gas supply system 130 and to control the chamber pressure accordingly.

DC power can be supplied from DC power source 105 to the titanium target 125. The controller 190 can be used to determine the amount of DC power to provide and when to have it applied to the target. For example, the DC power can range from 1000 W to 10,000 W, and can be 5,000 W. Alternatively, the power source 105 may be configured for supplying radio frequency (RF) power to the titanium target 125.

The controller 190 can be configured to provide control data to the system components and receive process and/or status data from the system components. In addition, the controller 190 may be coupled to another control system (not shown), and can exchange information with the other control system. For example, the controller 190 can comprise a microprocessor, a memory (e.g., volatile or non-volatile memory), and a digital I/O port capable of generating control voltages sufficient to communicate and activate inputs to the PVD system 100 as well as monitor outputs from the PVD system 100. Moreover, the controller 190 can exchange information with the system components, and a program stored in the memory can be utilized to control the aforementioned components of the PVD system 100 according to a process recipe. In addition, the controller 190 can be configured to analyze the process and/or status data, to compare the process and/or status data with desired process and/or status data, and to use the comparison to change a process and/or control a system component. In addition, the controller 190 can be configured to analyze the process and/or status data, to compare the process and/or status data with historical process and/or status data, and to use the comparison to predict, prevent, and/or declare a fault.

FIG. 1A further shows a magnet assembly 135 coupled to the process chamber 120. The magnet assembly 135 may be used to shape the plasma within the plasma region 122 in the process chamber 120. Examples of systems having minimized and controllable magnetic fields are described in U.S. Pat. App. 20040188239, and this patent application is incorporated herein by reference. As shown in FIG. 1A, the magnet assembly 135 can be located behind the titanium target 125 and can be used to produce and/or change a static magnetic field shape in within the plasma region 122 in the process chamber 120. In one embodiment, titanium nitride deposition process can be performed using a magnet assembly 135 having a weak magnetic field strength. Field lines from the magnets can extend into the process volume. In alternate embodiments, these or other field lines present in the chamber may be caused to change to enhance the titanium nitride deposition process. For example, magnetic fields may be changed by controlling the magnet configuration, by physically moving and/or rotating a magnet. In addition, an electromagnet or electromagnet component may be used to change a magnetic field. In addition, a local static magnetic field may be used to optimize the performance of the target. Some magnet pack configurations for PVD may typically produce static magnetic field strength at the target surface of over 150 Gauss or several hundred Gauss, to provide confinement of the plasma and a desired erosion profile and high target utilization. Reducing the static magnetic field strength at target surface to about 5-10 Gauss eliminates this confinement effect. According to some embodiments of the invention, the magnet assembly 135 may be omitted from the PVD system 100.

In various embodiments, one or more process parameters can be measured and compared with desired process parameters to control the operation of one or more components of the PVD system 100. The measured performance can be used to alter one or more process parameters, such as a DC-on time, a shaping plasma process time, a DC-off time, a DC power, ICP power, backside gas pressure, substrate holder temperature, substrate temperature, process gas flow rate, process chamber pressure, and deposition rate.

FIG. 1B illustrates an exemplary block diagram of a processing system according to an alternate embodiment of the invention. The PVD system 101 is similar to the PVD system 100 described in FIG. 1A but further contains a gas delivery ring 126 connected to the gas line 128 and the process gas supply system 130 and arranged circumferentially above the substrate 111 in the process chamber 120. The gas delivery ring 126 contains a plurality of holes 129 for introducing nitrogen gas proximate the upper surface of the substrate 111 facing the titanium target 125. In one example, the plurality of holes 129 can face towards the center of the upper surface of the substrate 111. According to some embodiments of the invention, the magnet assembly 135 may be omitted from the PVD system 101.

Embodiments of the invention provide a method for depositing low-electrical resistivity titanium nitride film using an ICP PVD system, where the deposition is performed in metal mode. According to embodiments of the invention the processing conditions are selected such that the argon ion sputtering of the titanium target results in substantially only neutral titanium atoms and substantially no titanium ions being sputtered from the titanium target. Furthermore, the processing conditions are selected such that the sputtered neutral titanium atoms are not ionized but are further thermalized prior to reaching the substrate surface where they are nitrided to form titanium nitride. Since the titanium atoms are neutral and thermalized, any potential substrate damage due to the titanium atoms impinging on the substrate is minimized or eliminated. Furthermore, the substrate holder may be electrically floating (i.e., no bias applied) to further reduce or prevent any ions from the plasma environment interacting with the substrate surface.

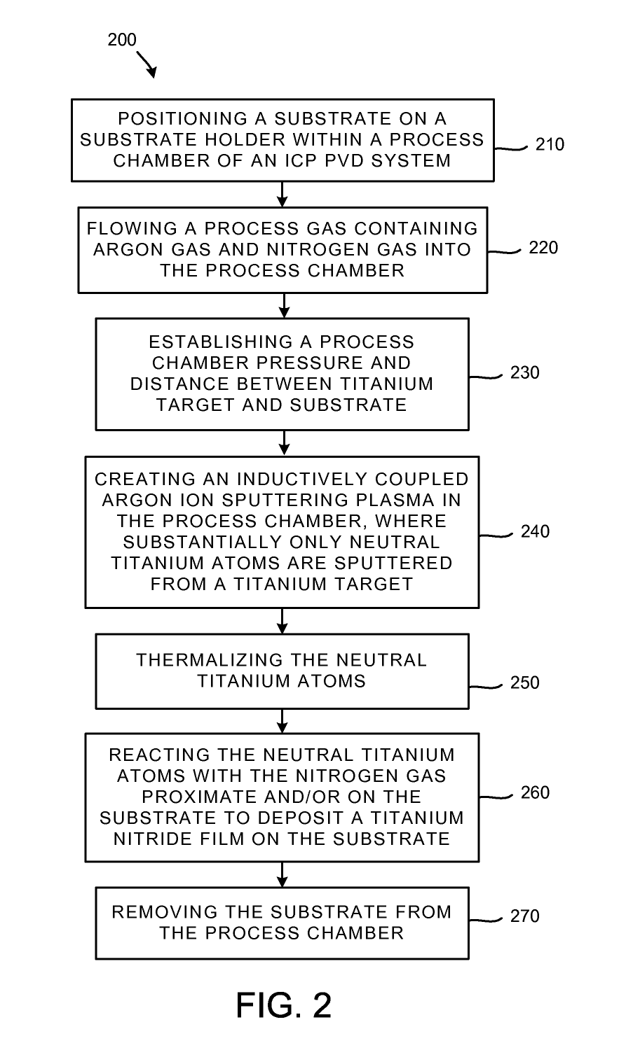

FIG. 2 illustrates a simplified flow diagram of a method of operating a processing system to perform a titanium nitride deposition process according to an embodiment of the invention. The process flow 200 may, for example, be performed using PVD system 100 shown in FIG. 1A or PVD system 101 shown in FIG. 1B.

In block 210, a substrate is positioned on a substrate holder within a process chamber. The temperature of the substrate holder and the substrate is controlled to obtain the good titanium nitride deposition, for example between 25° C. and 400° C.

In block 220, a process gas containing argon gas and nitrogen gas is flowed into the process chamber from a gas supply system. According to one embodiment of the invention, the argon gas flow rate can range from 100 sccm (standard cubic centimeters per minute) to 350 sccm, and the nitrogen gas flow rate can range from 20 sccm to 40 sccm. It was observed that nitrogen gas flow rates above 40 sccm changed the titanium nitride deposition mode from metal mode to poison mode. Titanium nitride films deposited in poison mode had electrical resistivities greater than 500 microohm-cm.

In block 230, a process chamber pressure and distance between the titanium target and the substrate are established. According to embodiments of the invention, the process chamber pressure and the distance between the titanium sputtering target and the substrate are selected effective to thermalize sputtered neutral titanium atoms by collisions with the process gas. Acceptable combinations of the process chamber pressure and the distance may be determined by measuring various properties of the deposited titanium nitride films, for example the electrical resistance. A pressure control system is utilized to achieve a selected process chamber pressure. The pressure control system is capable of maintaining the desired process chamber pressure for a large range of argon and nitrogen gas flow rates. According to some embodiments of the invention, a process chamber pressure ranging from 25 mTorr to 65 mTorr may be established in the process chamber. In one example, the argon flow rate can be about 217 sccm, the nitrogen gas flow rate can be about 35 sccm, and the process chamber pressure can be about 35 mTorr. During a titanium nitride deposition process, the substrate-to-target distance can typically range from approximately 150 to approximately 300 mm. According to one embodiment of the invention, for a given process chamber pressure (e.g., pressure between 25 mTorr and 65 mTorr) a substrate-to-target distance may be selected that exceeds the mean free path of the sputtered neutral titanium atoms, thereby thermalizing the sputtered neutral titanium atoms by collisions with the process gas prior to reaching the substrate.

In block 240, an inductively coupled argon ion sputtering plasma is created in the process chamber. The ICP processing conditions are selected such that substantially only neutral titanium atoms are formed by sputtering from the titanium target. This includes selecting RF power supplied to the antenna that is below a power level required to ionize a significant portion the sputtered neutral titanium atoms from the time they are sputtered from the titanium target to the time they are deposited on the substrate. The ICP processing conditions can include ICP plasma power ranging from 100 W to 1000 W, or from 200 W to 500 W, for example 500 W, applied to an antenna from a RF generator. The ICP processing conditions further include applying electric power, for example DC power, to the titanium target from a power source (e.g. a DC power source). The DC power can range from 1,000 Wk watts to 10,000 W, and can be 5,000 W. According to one embodiment of the invention, the substrate holder can be electrically floating. According to another embodiment of the invention, the substrate and the substrate holder may be grounded. According to yet another embodiment of the invention, the substrate may be biased by applying RF bias power to an electrode in the substrate holder using a RF bias generator.

In block 250, the neutral titanium atoms sputtered from the titanium target are thermalized by gas phase collisions before the neutral titanium atoms reach the substrate.

In block 260, the neutral titanium atoms are reacted with the nitrogen gas proximate and/or on the substrate to form a titanium nitride film on the substrate.

According to one embodiment of the invention, titanium nitride films can be deposited on a substrate using an argon flow rate of about 217 sccm, a nitrogen gas flow rate of about 35 sccm, process chamber pressure of about 35 mTorr, ICP plasma power of about 500 W that is applied to the antenna from a RF generator, DC power of 5,000 W applied to the titanium target from a DC power source, and the substrate holder and the substrate electrically floating. The titanium nitride deposition rate can be about 3.2 nm/min, the titanium nitride electrical resistivity can be about 170 microohm-cm, and the N/Ti atomic ratio can be about 0.9-1.

In block 270, the substrate is removed from the process chamber.

According to one embodiment of the invention, a method is provided for operating an Inductively Coupled Plasma (ICP) Physical Vapor Deposition (PVD) system. The method includes positioning a substrate on a substrate holder within a process chamber of the ICP PVD system, the ICP PVD system further comprising a metal target, a dielectric window, and an antenna. The method further includes performing a film deposition process by flowing a process gas containing a sputtering gas into the process chamber, applying electrical power to the metal target, creating an ICP argon ion sputtering plasma in the process chamber by applying radio frequency (RF) power to the antenna to sputter neutral metal atoms from the metal target, wherein the RF power is below a power level required to ionize a significant portion the sputtered neutral metal atoms. The method further includes selecting a combination of process gas pressure in the process chamber and distance between the metal target and the substrate effective to thermalize the neutral metal atoms by collisions with the process gas prior to reaching the substrate, depositing a metal-containing film containing the neutral sputtered metal atoms on the substrate, and removing the substrate from the process chamber.

The metal target can contain titanium, tantalum, tungsten, vanadium, chromium, manganese, iron, nickel, copper, zinc, yttrium, zirconium, niobium, molybdenum, ruthenium, rhodium, palladium, silver, cadmium, hafnium, rhenium, iridium, platinum, gold, or aluminum. Furthermore, the depositing can further include reacting the neutral metal atoms with a reactant gas proximate to and/or on the substrate, where the reactant gas contains nitrogen-containing gas, an oxygen-containing gas, a nitrogen- and oxygen-containing gas, or a carbon-containing gas, or a combination thereof. The metal-containing film can contain a metal film, a metal nitride film, a metal oxide film, a metal oxynitride film, a metal carbide film, or a metal carbonitride film, or a combination thereof.

A plurality of embodiments for depositing metal-containing films using an ICP PVD system have been described. The foregoing description of embodiments of the invention has been presented for the purposes of illustration and description. It is not intended to be exhaustive or to limit the invention to the precise forms disclosed. This description and the claims following include terms that are used for descriptive purposes only and are not to be construed as limiting.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method of operating an Inductively Coupled Plasma (ICP) Physical Vapor Deposition (PVD) system, the method comprising:
positioning a substrate on a substrate holder within a process chamber of the ICP PVD system, the ICP PVD system further comprising a metal target, a dielectric window, and an antenna;
performing a film deposition process, comprising:
flowing a process gas containing a sputtering gas into the process chamber,
applying electrical power to the metal target,
creating an ICP argon ion sputtering plasma in the process chamber by applying radio frequency (RF) power to the antenna to sputter neutral metal atoms from the metal target, wherein the RF power is below a power level required to ionize a significant portion the sputtered neutral metal atoms,
selecting a combination of process gas pressure in the process chamber and distance between the metal target and the substrate effective to thermalize the neutral metal atoms by collisions with the process gas prior to reaching the substrate, and
depositing a metal-containing film containing the neutral sputtered metal atoms on the substrate; and
removing the substrate from the process chamber.

2. The method of claim 1, wherein the metal target comprises titanium, tantalum, tungsten, vanadium, chromium, manganese, iron, nickel, copper, zinc, yttrium, zirconium, niobium, molybdenum, ruthenium, rhodium, palladium, silver, cadmium, hafnium, rhenium, iridium, platinum, gold, or aluminum.

3. The method of claim 2, wherein the metal-containing film comprises a metal film, a metal nitride film, a metal oxide film, a metal oxynitride film, a metal carbide film, or a metal carbonitride film, or a combination thereof.

4. The method of claim 1, wherein the depositing further comprises reacting the neutral metal atoms with a reactant gas proximate to and/or on the substrate, wherein the reactant gas comprises nitrogen-containing gas, an oxygen-containing gas, a nitrogen- and oxygen-containing gas, or a carbon-containing gas, or a combination thereof.

5. The method of claim 1, wherein the RF power applied to the antenna ranges from 100 W to 1,000 W and has a frequency between 1 MHz and 100 MHz.

6. The method of claim 5, wherein the RF power applied to the antenna ranges from 200 W to 500 W.

7. The method of claim 1, wherein the electrical power applied to the metal target comprises direct current (DC) power ranging from 1 k watts to 10 k watts.

8. The method of claim 1, wherein the process chamber pressure ranges from 25 mTorr to 65 mTorr.

9. The method of claim 1, wherein the substrate holder is electrically floating.

10. The method of claim 4, wherein the sputtering gas is introduced in the process chamber proximate the metal target and the reactant gas is introduced into the process chamber proximate the substrate.

11. The method of claim 4, wherein the reactant gas is introduced into the process chamber using a gas delivery ring arranged circumferentially above the substrate and containing a plurality of holes.

12. The method of claim 1, wherein the process gas is introduced into the process chamber below the substrate.

13. The method of claim 1, wherein the substrate holder is vertically translated to establish the distance between the metal target and the substrate, wherein the distance ranges from approximately 150 mm to approximately 300 mm.

14. The method of claim 1, wherein a gas flow rate of the sputtering gas ranges from 100 sccm to 350 sccm.

15. The method of claim 4, wherein a gas flow rate of the reactant gas ranges from 20 sccm to 40 sccm.

16. The method of claim 4, wherein a gas flow rate of the sputtering gas ranges from 100 sccm to 350 sccm and a gas flow rate of the reactant gas ranges from 20 sccm to 40 sccm.

17. The method of claim 4, wherein a gas flow rate of the sputtering gas is approximately 217 sccm and a gas flow rate of the reactant gas is approximately 35 sccm.

18. A method of operating an Inductively Coupled Plasma (ICP) Physical Vapor Deposition (PVD) system to deposit a titanium nitride film on a substrate, the method comprising:
positioning the substrate on a substrate holder within a process chamber of the ICP PVD system, the ICP PVD system further comprising a titanium target, a dielectric window, and an antenna;
performing a titanium nitride deposition process in metal mode, comprising:
flowing a process gas containing argon gas and nitrogen gas into the process chamber,
establishing a process chamber pressure between 25 mTorr and 65 mTorr in the process chamber,
applying DC power between 1,000 W and 10,000 W to the titanium target,
creating an ICP argon ion sputtering plasma in the process chamber by applying radio frequency (RF) power to the antenna to sputter neutral titanium atoms from the titanium target, wherein the RF power is below a power level required to ionize a significant portion of the sputtered neutral titanium atoms,
selecting a combination of the process gas pressure in the process chamber and the distance between the titanium target and the substrate effective to thermalize the neutral titanium atoms by collisions with the process gas, and
reacting the neutral titanium atoms with the nitrogen gas proximate and/or on the substrate to deposit the titanium nitride film on the substrate; and
removing the substrate from the process chamber.

19. The method of claim 18, wherein the substrate holder is electrically floating.

20. The method of claim 18, wherein the argon gas is introduced in the process chamber proximate the titanium target and the nitrogen gas is introduced into the process chamber proximate the substrate.

21. The method of claim 18, wherein the RF power applied to the antenna ranges from 100 W to 1,000 W watts.

22. The method of claim 18, wherein the substrate holder is vertically translated to establish the distance between the titanium target and the substrate holder.

23. The method of claim 18, wherein a gas flow rate of the argon gas ranges from 100 sccm to 350 sccm and a gas flow rate of the nitrogen gas ranges from 20 sccm to 40 sccm.
